(19) United States
(12) Patent Application Publication
(10) Pub. No.: US 2005/0150862 A1
(43) Pub. Date: Jul. 14, 2005

(54) Workpiece alignment assembly

(76) Inventors: Bruce M. Harper, San Jose, CA (US); Christopher H. Bajorek, Los Gatos, CA (US)

Correspondence Address: Daniel E. Ovanezian;BLAKELY, SOKOLOFF, TAYLOR & ZAFMAN LLP, Seventh Floor, 12400 Wilshire Boulevard, Los Angeles, CA, 90025, US

(21) Appl. No.: 10/757,794

(22) Filed: Jan. 13, 2004

(51) Int. Cl. B44C 1/22; H01L 21/76

(52) U.S. Cl. 216/22

(57) ABSTRACT

A workpiece alignment assembly. The assembly may include an embossing foil, a nest having a gas-bearing surface to receive a substrate, and piezo actuators disposed near the gas-bearing nest. In one embodiment, the piezo actuators center the substrate relative to the embossing foil.

### TECHNICAL FIELD

Embodiments of this invention relate to the field of magnetic recording disks and, more specifically in one embodiment, to the manufacturing of magnetic recording disks.

### BACKGROUND

A disk drive system includes one or more magnetic recording disks and control mechanisms for storing data within approximately circular tracks on the disk. A disk is composed of a substrate and one or more layers deposited on the substrate (e.g., aluminum). A trend in the design of disk drive systems is to increase the recording density of the magnetic recording disk used in the system. One method for increasing recording density is to pattern the surface of the disk with discrete tracks, referred to as discrete track recording (DTR). A DTR pattern may be formed by nano-imprint lithography (NIL) techniques, in which a rigid, pre-embossed forming tool (a.k.a., stamper, embosser, etc.), having an inverse pattern to be imprinted, is pressed into an embossable film (i.e., polymer) disposed above a disk substrate to form an initial pattern of compressed areas. This initial pattern ultimately forms a pattern of raised and recessed areas. After stamping the embossable film, an etching process is used to transfer the pattern through the embossable film by removing the residual film in the compressed areas. After the imprint lithography process, another etching process may be used to form the pattern in a layer (e.g., substrate, nickel-phosphorous, soft magnetic layer, etc.) residing underneath the embossable film.

One prior DTR structure forms a pattern of concentric raised areas and recessed areas under a magnetic recording layer. The raised areas (also known as hills, lands, elevations, etc.) are used for storing data and the recessed areas (also known as troughs, valleys, grooves, etc.) provide inter-track isolation to reduce noise. The raised areas have a width less than the width of the recording head such that portions of the head extend over the recessed areas during operation. The recessed areas have a depth relative to fly height of a recording head and raised areas. The recessed areas are sufficiently distanced from the head to inhibit storage of data by the head in the magnetic layer directly below the recessed areas. The raised areas are sufficiently close to the head to enable the writing of data in the magnetic layer directly on the raised areas. Therefore, when data are written to the recoding medium, the raised areas correspond to the data tracks. The recessed areas isolate the raised areas (e.g., the data tracks) from one another, resulting in data tracks that are defined both physically and magnetically.

Isothermal pressing conditions are important to obtain high quality, high fidelity imprints on the embossable film disposed above the disk substrate. Prior to imprinting, the embossable film is heated to an ideal imprinting temperature. A transporting device, such as a chuck or robotic wand, transports the heated embossable film/disk substrate from a cassette to a disk nest area of the stamper. The temperature of the embossable film can fluctuate (typically the temperature drops) prior to imprinting because of the time required to transport the disk substrate to the stamper. The disk substrate transporter (e.g., robotic arm, wand) may act as heat sink because of the mechanical contact between the embossable film/disk substrate and the transporter. Because of the temperature inconsistencies within the embossable film/disk substrate, the imprinted pattern on the embossable film may be distorted resulting in non-viable disk substrates. Another problem is that most NIL systems require using molds and work pieces (e.g., embossable film coated disks) that have different coefficients of thermal expansion. The difference in the coefficients of thermal expansion in combination with temperature changes of the mold and work piece can cause strain or relative motion between the mold and work piece that exceed the precise dimensions sought by the NIL process.

Bernoulli wands have been used in semiconductor wafer manufacturing to allow for transport of a wafer without mechanical contact. A Bernoulli wand utilizes jets of gas to create a gas flow pattern above a wafer substrate that causes the pressure immediately above the wafer substrate to be less than the pressure immediately below the wafer. Consequently, the pressure imbalance causes the wafer substrate to experience an upward “lift” force. Moreover, as the substrate is drawn upward toward the wand, the same jets that produce the lift force produce an increasingly larger repulsive force that prevents the wafer from substantially contacting the Bernoulli wand. As a result, it is possible to suspend the wafer substrate below the wand in a substantially non-contacting manner. FIG. 1 illustrates a conventional Bernoulli wand pickup device that is also adapted to regulate the temperature of a wafer. As shown, a wafer is suspended below the Bernoulli wand. The Bernoulli wand is also connected to a gas reservoir that passes through a gas heater before flowing out towards the wafer.

This type of Bernoulli wand is not suitable for transporting a magnetic recording disk substrate to a receiving nest of a disk stamper, because the disk substrate could not be placed in the nest without the surface of the disk substrate (i.e., embossable film) making mechanical contact with the nest.

### BRIEF DESCRIPTION OF THE DRAWINGS

The present invention is illustrated by way of example, and not limitation, in the figures of the accompanying drawings in which:

FIG. 1 illustrates a prior Bernoulli pickup device.

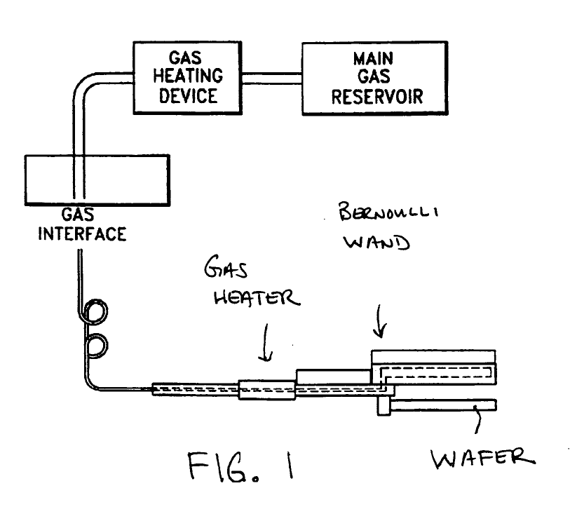

FIG. 2A illustrates one embodiment of a workpiece handler and alignment assembly.

FIG. 2B illustrates a side view of the workpiece handler and alignment assembly of FIG. 2A.

FIG. 2C illustrates a bottom view of the workpiece handler and alignment assembly of FIG. 2A.

FIG. 3A illustrates a cross-sectional, side view of the workpiece handler and alignment assembly of FIG. 2A.

FIG. 3B illustrates an enlarged cross-sectional, side view of the workpiece handler and alignment assembly of FIG. 2A.

FIG. 4A is a flow chart illustrating one embodiment of a method of imprinting an embossable film.

FIG. 4B is a flow chart illustrating an alternative embodiment of a method of imprinting an embossable film.

FIG. 4C is a flow chart illustrating another embodiment of a method of imprinting an embossable film.

FIG. 4D is a flow chart illustrating another embodiment of a method of imprinting an embossable film.

FIG. 5A is a cross sectional view illustrating one embodiment of an embossable film disposed above a disk substrate.

FIG. 5B is a cross sectional view illustrating one embodiment of the imprinting of an embossable film by an imprinting stamper.

FIG. 6A is a flow chart illustrating one embodiment of a method of imprinting an embossable film.

FIG. 6B is a flow chart illustrating an alternative embodiment of a method of imprinting an embossable film.

FIG. 6C is a flow chart illustrating another embodiment of a method of imprinting an embossable film.

### DETAILED DESCRIPTION

In the following description, numerous specific details are set forth such as examples of specific materials or components in order to provide a thorough understanding of the present invention. It will be apparent, however, to one skilled in the art that these specific details need not be employed to practice the invention. In other instances, well known components or methods have not been described in detail in order to avoid unnecessarily obscuring the present invention.

The terms “above,” “below,” “between,” and “adjacent” as used herein refer to a relative position of one layer or element with respect to other layers or elements. As such, a first element disposed above or below another element may be directly in contact with the first element or may have one or more intervening elements. Moreover, one element disposed next to or adjacent another element may be directly in contact with the first element or may have one or more intervening elements.

It should be noted that the apparatus and methods discussed herein may be used with various types of substrates (e.g., disk substrates and wafer substrates). In one embodiment, the apparatus and methods discussed herein may be used for the imprinting of embossable materials for the production of magnetic recording disks. The magnetic recording disk may be, for example, a DTR longitudinal magnetic recording disk having, for example, a nickel-phosphorous (NiP) plated substrate as a base structure. Alternatively, the magnetic recording disk may be a DTR perpendicular magnetic recording disk having a soft magnetic film disposed above a substrate for the base structure. In an alternative embodiment, the apparatus and methods discussed herein may be used for the imprinting of other types of digital recording disks, for example, optical recording disks such as a compact disc (CD) and a digital-versatile-disk (DVD). In yet other embodiments, the apparatus and methods discussed herein may be used in other applications, for examples, the production of semiconductor wafers, and display panels (e.g., liquid crystal display panels).

Apparatus and methods for the imprinting an embossable film disposed above a substrate using a workpiece handler and alignment assembly are described. By way of example only, embodiments of a workpiece handler and alignment assembly are described with respect to a disk substrate. However, it may be appreciated by one of skill in the art that embodiments of a workpiece handler and alignment assembly may be easily adapted for substrates that vary in shape and size (e.g., square, rectangular, etc.), for the production of different types of substrates discussed above. In one embodiment, the apparatus and methods described herein may be used for the fabrication of disks utilizing nano-imprinting lithography techniques. In one embodiment, a pickup head is positioned in close proximity to a horizontally presented disk substrate. Gas (e.g., air) is gradually admitted into a first port where it is distributed around an annular manifold. A turbulent gas distributor disposed near the annular manifold equalizes the gas flow/pressure exiting an gas knife gap around the disk substrate. The high velocity gas flow clings to the flat underside of the pickup head by means of the Coanda effect.

The radially flowing high velocity gas creates a substantial low pressure which attracts the disk substrate in close proximity to the under surface of the head. However, positive gas pressure prevents the disk substrate from ever touching the head. Guide pins in proximity to a disk substrate outer diameter (OD) edge prevent the disk from coasting off the head. Once the disk is positioned over a receiving tool nest of a die assembly (i.e., stamper), gas flow is directed to central radial jets which blow gas into the disk substrate inner diameter (ID) hole creating a positive gas pressure cushion under the disk. Disk substrate positioning elements disposed within the nest guide the disk to a desired location. In one embodiment, a workpiece alignment assembly having piezo actuators center the disk substrate with a centerline of the embossing foils disposed within the die assembly. One advantage of a Bernoulli-type pickup head is that pre-heated embossable film/disk substrates may be handled without the problem of melting plastic gripping surfaces, as in prior art pickup devices. The same pickup head may be used to remove the disk substrate after stamping using cooled gas to ease subsequent handling and deposition into, for example, plastic cassettes.

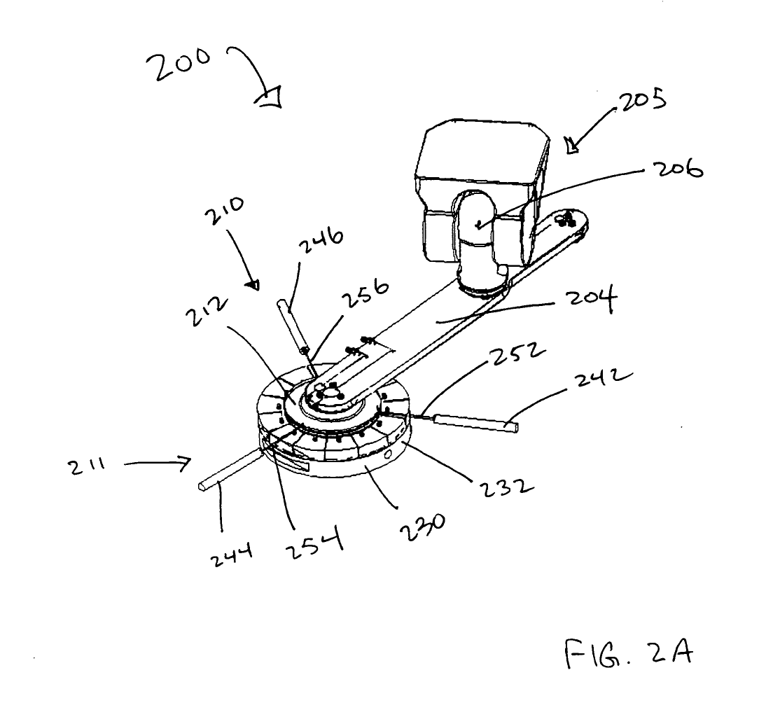

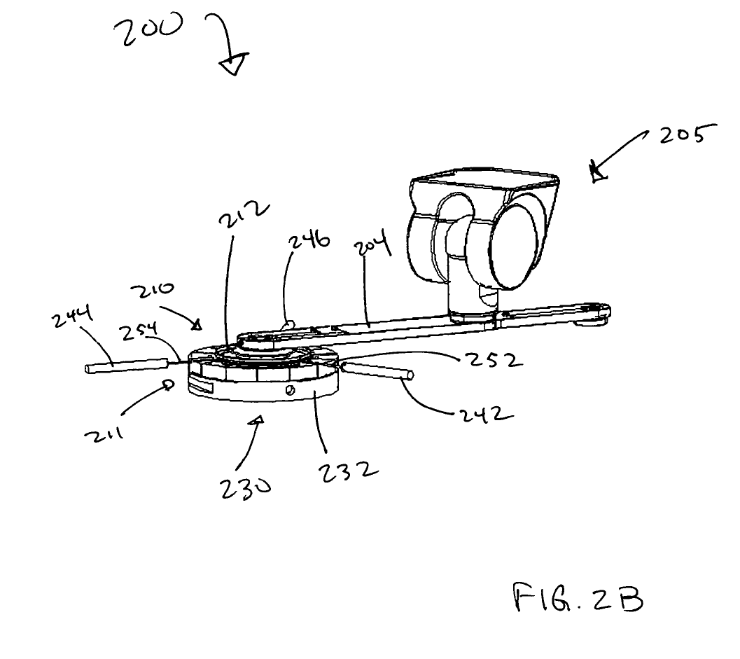

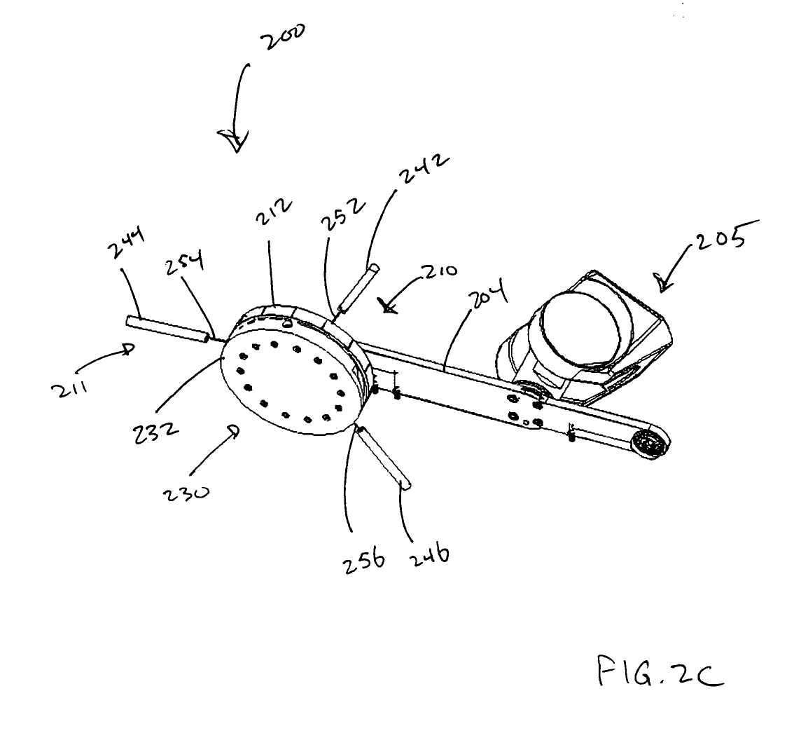

FIGS. 2A-2C illustrate various views of one embodiment of a workpiece handler and alignment assembly 200. By way of example only, assembly 200 is described with respect to the handling and alignment of a disk substrate for imprinting of an embossable layer disposed above the substrate. However, it will be appreciated that assembly 200 may be used for the handling and alignment other types of substrates having various shapes and sizes. Assembly 200 includes a workpiece handler 210 and a workpiece alignment assembly 211 positioned near die assembly 230. Handler 210 includes a robotic arm 205 coupled to an elongated arm portion 204 with joint 206. Joint 206 allows arm 205 to move both laterally and longitudinally relative to die assembly 230. A pickup head 212 is coupled to arm portion 204. Die assembly 230 includes a lower die portion 232, an embossing foil (not shown) disposed on a top surface of lower die portion 232, and a disk substrate (not shown) centered over the embossing foil. In one embodiment, workpiece alignment assembly 211 has one or more push rods (e.g., rods 252, 254, 256) disposed around lower die assembly 232 to engage an outer diameter of a disk substrate. Each rod is coupled to an actuator (e.g., actuators 242, 244, 246) of workpiece aligner 211. In one embodiment, actuators 242, 244, 246 may be piezo actuators that control push rods 252, 254, 256 to center the disk substrate relative to the embossing foil.

In one embodiment, workpiece handler 210, workpiece alignment assembly 211, and die assembly 230 are part of a larger embossable film imprinting assembly in which robotic arm 205 transports a disk substrate from a tray or cassette (not shown) that holds a number of disk substrates that are ready to be embossed with die assembly 230. In alternative embodiments, other types of pick and place devices may be used for robotic arm 205. As described in greater detail below, a combination of substantial low pressure and positive gas pressure around a disk substrate creates a Bernoulli effect that allows pickup head 212 to transport a disk substrate without any mechanical contact with the disk surface(s). The disk substrate may then be safely transported to a nest area of lower die portion 232. Die assembly 230, in an alternative embodiment, may be part of a larger assembly that includes an upper die portion (not shown) in addition to lower die portion 232, with each portion having an embossing foil. The combination of upper and lower die portions allows both sides of a disk substrate (with embossable films on both surfaces) to be imprinted simultaneously. In one embodiment, the disk substrate initially rests on a cushion of gas above an embossing foil when released from pickup head 212.

One or more push rods 252, 254, 256 are disposed around die assembly 230, and in one embodiment, positioned above the embossing foil and in a plane aligned with the disk substrate. Each push rod is coupled to corresponding actuators 242, 254, 256. In one embodiment, the combination of rods and actuators may form a 3-jaw chuck to engage the OD of a disk substrate. Rods 252, 254, 256 engage the disk substrate to center it relative to a centerline of the embossing foil. Centering the imprint pattern (e.g., DTR pattern) relative to a centerline of the disk substrate is important to produce viable disks, particularly when both sides of the disk substrate are embossed, in which case both sides must be aligned. Actuators 242, 244, 246 may represent one of several mechanisms for achieving nano actuation. In one embodiment, actuators 242, 244, 246 may be piezo actuators. In an alternative embodiment, actuators 242, 244, 246 may be voice coil actuators. The centering of a disk substrate relative to an embossing foil may be done in real-time in which a known reference point on the embossing foil is checked against a known reference point on the disk substrate. Adjustments to the disk substrate may be dictated by an actuator controller (not shown) coupled to the piezo or voice coil actuators (e.g., 242, 244, 246).

In an alternative embodiment, assembly 200 has the ability to impart thermal qualities to the handling of disk substrates. An embossable film disposed above the disk substrate may be pre-heated to raise the temperature of the embossable film to an optimum embossing level. For example, the embossable film/disk substrate may be pre-heated prior to placement in a receiving cassette. Because of the non-contact nature of pickup head 212, embossable film/disk substrate 260 undergoes no temperature fluctuation or thermal dissipation from mechanical contact with pickup head 212. Moreover, the flow of gas through pickup head 212 may be heated to the optimum embossing temperature to maintain the desired temperature during transport to die assembly 230. In one embodiment, the embossable film may be heated to a temperature in the range of approximately 20 to 500 degrees C. There is minimal thermal dissipation even after placing embossable film/disk substrate above an embossing foil because the surface of embossable film/disk substrate rests on a cushion of gas instead of making mechanical contact with portions of the substrate receiving nest. Additionally, die assembly 230, including the embossable foil disposed therein, may be heated to a temperature close to the heated temperature of the embossable film. This thermal matching ensures distortion-free molded/imprinted features on the embossable film. The embossing foil may be designed to release and separate from the imprinted embossable film upon opening of lower die portion 232. At this point, pickup head 212 may use heated gas to pickup and transport the disk substrate so as not to cool parts of die assembly 230 (e.g., the embossing foil). As such, die assembly 230 maintains a constant embossing or imprinting temperature. Once in a position away from die assembly 230, heated gas may be replaced with cooled gas to drop the temperature of the disk substrate prior to placing it in another receiver or cassette. Because no significant mechanical contact occurs between the embossable film and pickup head 212, there are no heat sinks or hot spots on surfaces of the disk substrate to cause distortion.

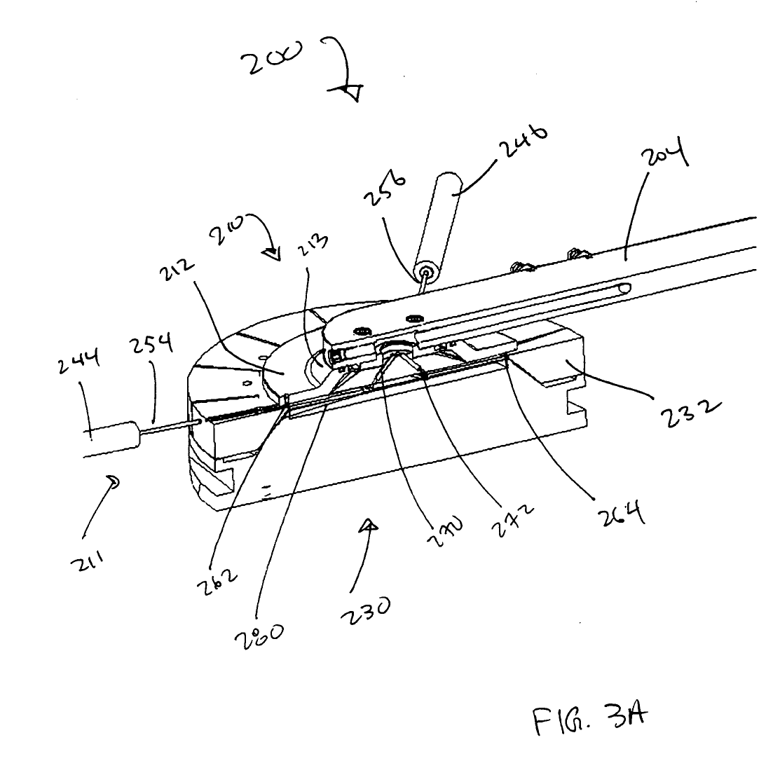

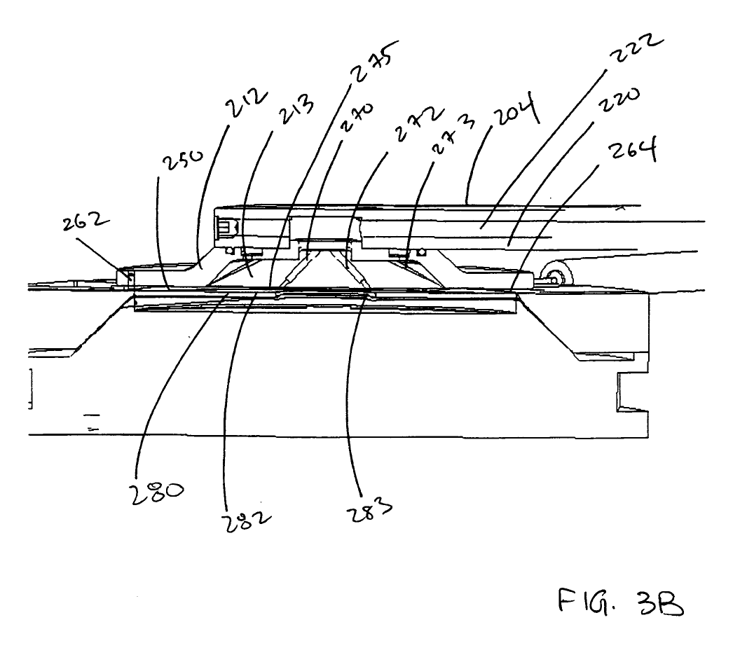

FIGS. 3A-3B illustrate various cross-sectional views of workpiece handler and alignment assembly 200. Pick-up head 212 is coupled to elongated arm portion 204 with a disk substrate 250 disposed within lower die assembly 232. In this embodiment, pick-up head 212 includes one or more ports that lead to gas channels, including first port 220 and second port 222, that extend through elongated arm portion 204 and into manifold body 213 of pickup head 212. First port 220 and second port 222 are coupled to separate gas valves (not shown). One or more guide pins (e.g., 262, 264) are disposed around an outer dimension of manifold body 213. A flow of gas through port 220 travels down one or more grooves 270, 272 disposed around manifold 213 to create an even gas distribution around annular gas slot 275. This results in a Bernoulli effect for supporting disk substrate 250 below manifold body 213. Guide pins 262, 264 prevent disk substrate 250 from coasting off pickup head 212.

FIGS. 3A-3B also illustrate disk substrate 250 supported by Bernoulli gas flow and positioned above an embossing nest or die cavity 280. Pickup head 212 coupled to arm 204 supports disk substrate 250 below manifold body 213 and within an area defined by guide pins 262, 264. A third guide pin (not shown) may be disposed equidistant from guide pins 262, 264. Pickup head 212 may be positioned to hover disk substrate 250 above die assembly 230 that includes lower die portion 232. A disk receiving nest 280 for disk substrate 250 is formed near a top surface of lower die portion 232, as well as embossing foil 282 disposed above receiving nest 280 and below disk substrate 250. In one embodiment, pickup head 212 may precisely control the lowering of disk substrate 250 to about 0.5 mm above receiving nest 280 of lower die portion 232. At this point, the Bernoulli support by pickup head 212 may be stopped, and disk substrate 250 may float on a cushion of gas flowing on a surface of receiving nest 432 that also constrains disks substrate to an area defined by the walls of receiving nest 432.

Once pickup head 212 is positioned over the flat, horizontal surface of disk substrate 250, gas is gradually admitted through first port 220 and is distributed around annular manifold 213. Gas flow is passed through grooves 272, 274 around annular manifold 213 which tends to equalize the gas flow/pressure exiting a gas slot 275 around an outer dimension (e.g., edge or diameter) of disk substrate 250. The high velocity gas flow clings to the flat underside of pickup head 212 by way of the Coanda effect. The radially flowing high velocity gas through port 220 creates a substantial low pressure that holds disk substrate 250 in close proximity to the undersurface of pickup head 212. However, positive gas pressure prevents disk substrate 250 from touching any part of pickup head 212. Guide pins 262, 264 prevent disk substrate 250 from coasting off pickup head 212.

Once disk substrate is positioned over receiving nest 280, gas flow from first port 220 is gradually stopped and gas flow through second port 422 is initiated. Second port 422 directs the gas flow through jets (not shown) disposed within pick-up head 212 that are aimed toward a hole formed by an inner diameter 283 of disk substrate 250. The flow of gas through ID hole 283 creates a positive gas pressure cushion under disk substrate 250 to suspend it within receiving nest 280. As such, there is no mechanical contact between a surface of disk substrate 250 and parts of pickup head 212 and receiving nest 280 prior to the centering of disk substrate 250 relative to embossing foil 282.

To center disk substrate 250 relative to embossing foil 282, actuators 242, 244, 246 extends push rods 252, 254, 256 to engage an outer diameter of disk substrate 250. It should be noted that, with respect to FIGS. 3A-3B, only two actuators and push rods are shown. However, in an alternative embodiment, multiple actuators and rods may be disposed around the disk substrate (e.g., actuators 242, 244, 246 and rods 252, 254, 256 as discussed above with respect to FIGS. 2A-2C). When multiple push rods are used, they engage the OD of disk substrate 250 in synchronism in the manner of a 3-jaw chuck. The push rods may be used to center disk substrate 250 relative to a centerline of embossing foil 282, establishing a centering position for subsequent disk substrates. In one embodiment, actuators 242, 244, 246 may be ways to for achieving nano actuation. In one embodiment, actuators 242, 244, 246 may be piezo actuators. In an alternative embodiment, actuators 242, 244, 246 may be voice coil actuators. Once disk substrate 250 is centered relative to embossing foil 282, encoders coupled to actuators 242, 244, 246 may sense motion stoppage, allowing an actuator controller (not shown) to hold the position of rods 252, 254, 256 and securely clamp disk substrate 250. All gas flow from pickup head 212 may be stopped and pickup head 212 may then be withdrawn from a position above receiving nest 280. Embossing foil 282 may then be pressed into the embossing film of disk substrate 250. Subsequent disk substrates may be checked for drift from the original centering alignment, and the actuator controller may be adjusted in real-time to reposition a disk substrate. As such, the use of one or more actuators/push rods may be biased to attain an infinite number of centering positions for a disk substrate relative to an embossing foil.

FIG. 3B illustrates an enlarged cross-sectional view of disk substrate 250 being supported by a cushion of gas within receiving nest 280 of lower die assembly 232. In one embodiment, the cushion of gas supports disk substrate 250 such that it is approximately 0.5 mm above embossing foil 282 and horizontally aligned with push rods 252, 254, 256. As discussed above, lower die portion 232 may include three push rods 252, 254, 256 coupled to actuators 242, 244, 246, respectively. The push rods/actuators are spaced equidistant from each other as to maximize their effectiveness in securing disk substrate 250. Push rods 252, 254, 256 extend into a space between disk substrate 250 and embossing foil 282. As discussed above, actuators 242, 244, 246 engage the OD of disk substrate 250 in synchronism in the manner of a 3-jaw chuck. The push rods may be used to center disk substrate 250 relative to a centerline of embossing foil 282, establishing a centering position for subsequent disk substrates. Once disk substrate 250 is centered, encoders coupled to actuator 242, 244, 246 may sense motion stoppage, allowing an actuator controller (not shown) to hold the position of push rods 252, 254, 256 and securely clamp disk substrate 250 for imprinting the embossable film.

After imprinting disk substrate 250, gas may be directed through second port 422 and through jets (not shown) disposed within pick-up head 212 that are aimed toward a hole formed by an inner diameter 283 of disk substrate 250. The flow of gas through ID hole 283 creates a positive gas pressure cushion under disk substrate 250 to suspend it within receiving nest 280. Actuators 242, 244, 246 may be disengaged or released from the outer edge of disk substrate 250. Disk substrate 250 may then be removed from receiving nest 280 with pick-up head 212. As such, the flow of gas through the hole formed by inner diameter 283 aids in the removal of disk substrate 250 by pick-up head 212.

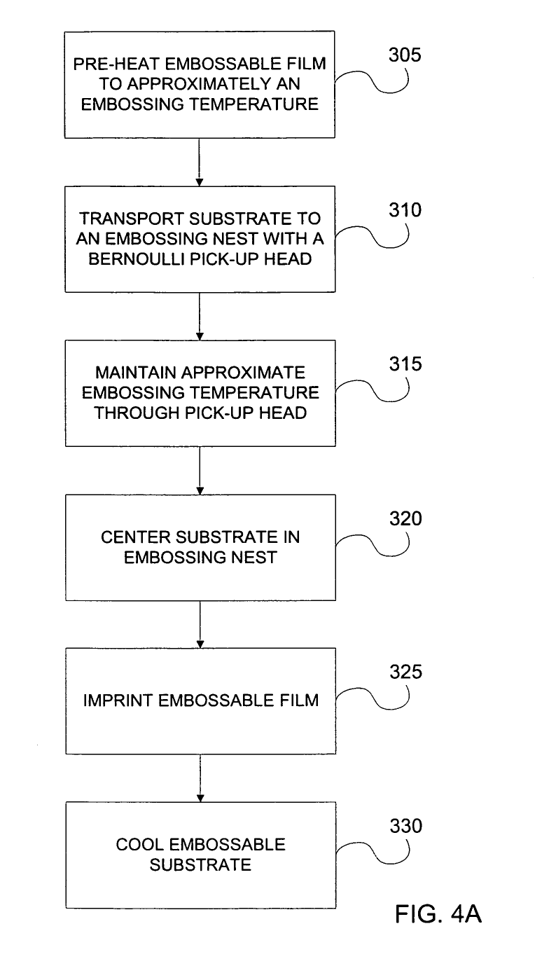

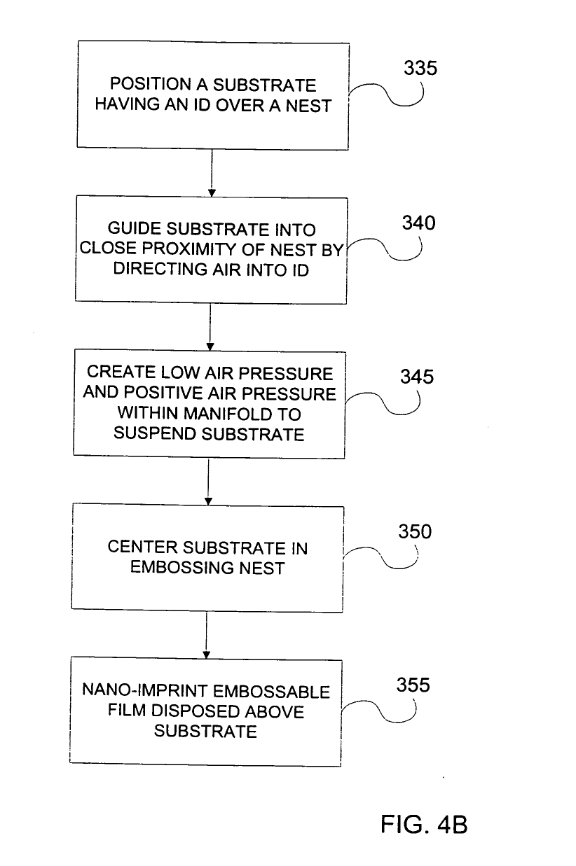

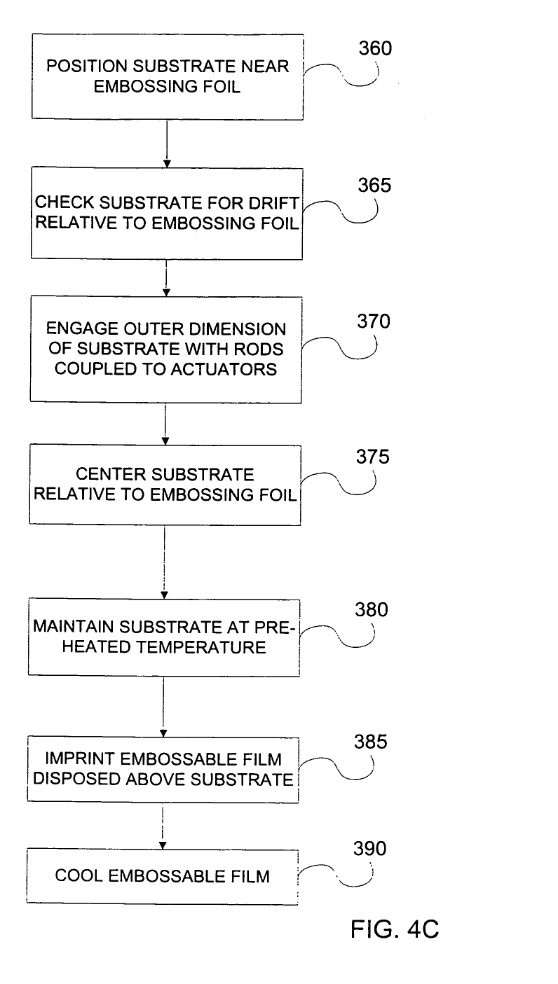

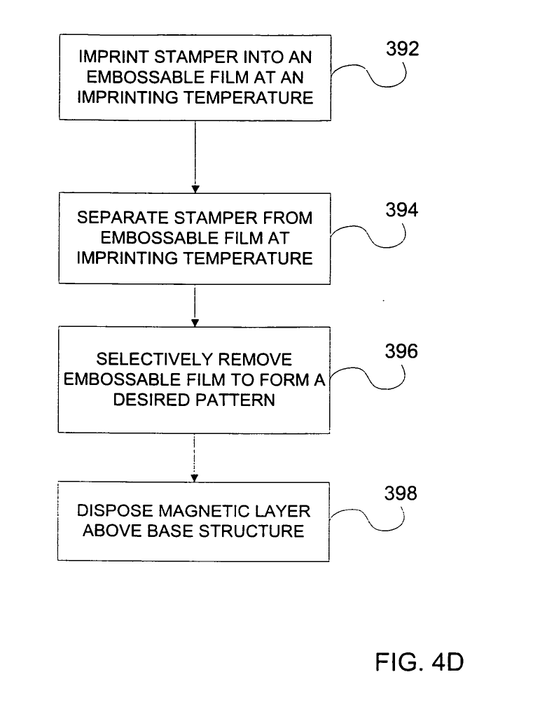

As previously mentioned, the apparatus and methods discussed above may be used, in one embodiment, for the imprinting of an embossable layer disposed above a base structure of a disk substrate. FIGS. 4A-4D illustrate embodiments of a method of imprinting a substrate with an imprinting system. An embossable film disposed above a substrate (e.g., a disk substrate) is pre-heated (e.g., with pick-up head 212), to an embossing temperature, step 305. The substrate may be transported to an embossing nest (e.g., nest 280) with a Bernoulli pick-up head (e.g., pick-up head 212), step 310. The embossing nest may also be pre-heated or have the substantially same embossing temperature of the pick-up head. In one embodiment, the approximate embossing temperature is maintained during transport to the embossing nest, step 315. Once placed in the embossing nest, the substrate is centered or aligned relative to an embossing foil (e.g., embossing foil 282) disposed within a die assembly, step 320, followed by imprinting, step 325. The imprint pattern on the embossable film of the substrate may then be cooled, step 330.

In an alternative embodiment illustrated in FIG. 4B, a substrate (e.g., disk 250) is positioned over a nest (e.g., nest 280) of an imprinting die assembly (e.g., assembly 230), step 335. The substrate is then guided into close proximity of the nest by directing gas into an inner diameter of the substrate, step 340. A pick-up head that handles the substrate creates low gas pressure and positive gas pressure within a manifold (e.g., 213) to suspend the substrate, step 345. The substrate is then centered within the embossing nest 280 relative to an embossing foil (e.g., foil 282), step 350. The embossable film disposed above the substrate is imprinted, for example, by nano-imprint, step 355.

In yet another alternative embodiment illustrated in FIG. 4C, a substrate (e.g., substrate 250) is positioned near an embossing foil (e.g., foil 282), step 360. The substrate may then be inspected or checked for drift relative to the embossing foil, step 365 and the alignment corrected if necessary. The inspection and alignment may be performed prior to imprinting and/or after imprinting. One or more rods (e.g., rods 252, 254, 256) coupled to actuators (e.g., 242, 244, 246) engage an outer dimension (e.g., outer diameter of a disk) of the substrate, step 370, and the substrate is centered relative to the embossing foil, step 375. During the centering process, the substrate is maintained near a pre-heated, embossing temperature (e.g., with pick-up head 212), step 380. The embossing foil and/or nest may also be pre-heated to the embossing temperature. The embossable film disposed above the substrate is imprinted, step 385, and then cooled, step 390.

In yet another alternative embodiment illustrated in FIG. 4D, a stamper is imprinted into an embossable film at an imprinting temperature (e.g., 20-500 degrees C.), step 392. Following the stamping of the embossable film, the stamper is separated from the embossable film while still near the imprinting temperature, step 394. The embossable film is then selectively removed (e.g., via etching) to form a desired pattern (e.g., DTR pattern), step 396, and a magnetic layer may then be disposed above a base structure, step 398.

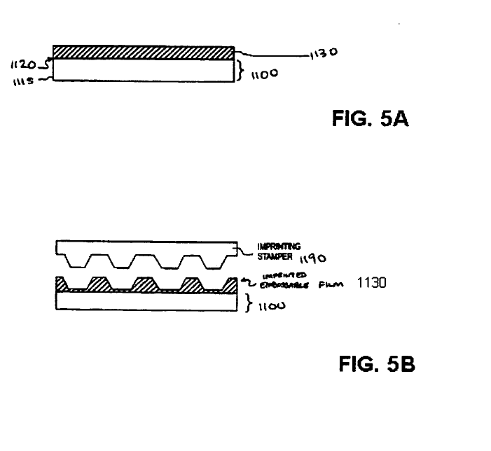

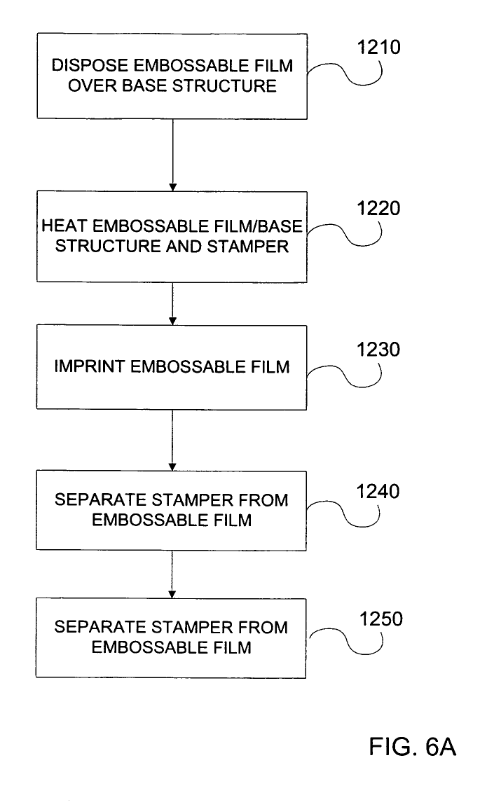

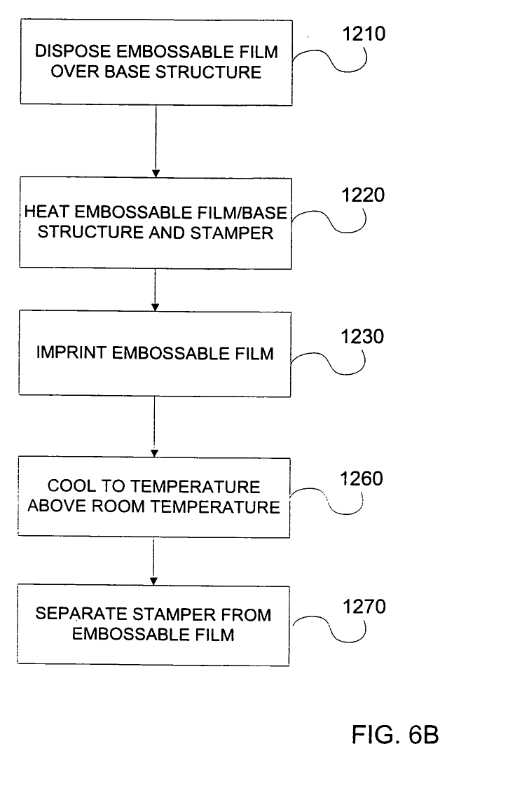

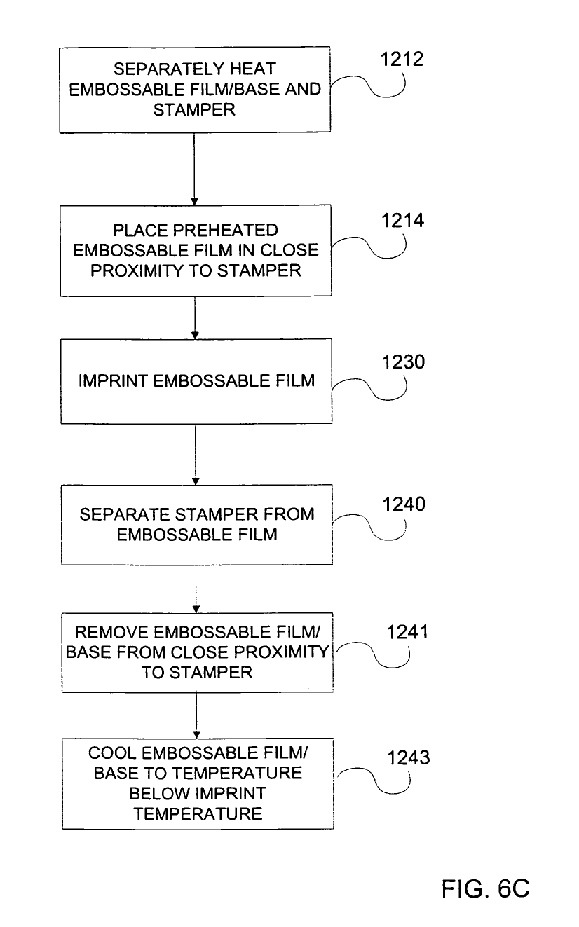

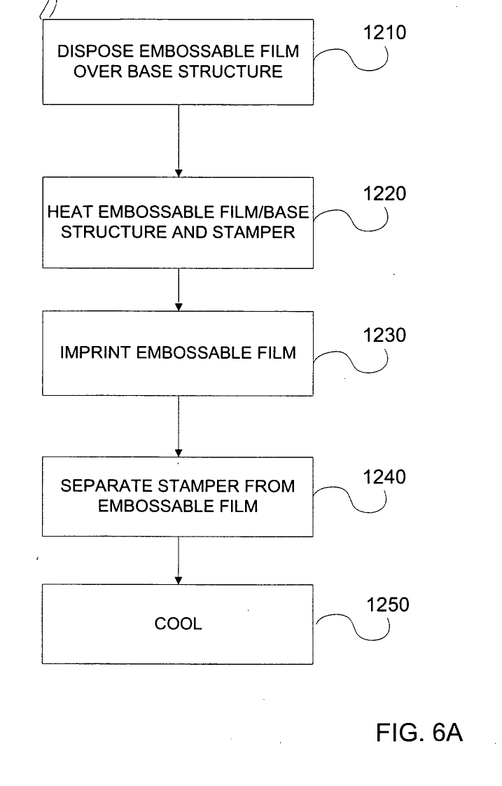

FIGS. 5A, 5B, 6A, 6B and 6C illustrate alternative embodiments of a method of imprinting an embossable film disposed above a base structure. The base structure may be a substrate, and in one particular embodiment, a disk substrate. The base structure may be transported to an embossing nest (e.g., nest 280) with a Bernoulli pick-up head (e.g., pick-up head 212), Embossable film 1130 is disposed over base structure 1115, step 1210. In one embodiment, embossable film 1130/base structure 1115 and stamper 1190 are heated at or above the “glass transition temperature” (Tg) of embossable film 1130, step 1220. The glass transition temperature is a term of art that refers to the temperature where a polymer material becomes viscoelastic above this temperature (which is different for each polymer).

Stamper 1190 is then pressed into the embossable film 1130, step 1230. In one embodiment, stamper 1190 is separated from embossable film 1130, step 1240, and then cooled after separation, step 1250. An imprinted pattern of trenches areas (a.k.a., recessed areas, grooves, valleys, etc.) and plateaus (a.k.a., raised areas) is thereby formed in the embossable film 1130 (as illustrated in FIG. 5B). The separation of stamper 1190 from embossable film 1130 before cooling may facilitate the separation process and result in less damage to the imprinted pattern in embossable film 1130.

In an alternative embodiment illustrated in FIG. 6B, the system may be cooled to a temperature above room temperature, step 1260, prior to the separation of stamper 1190 from embossable film 1130, step 1270. For example, where the embossable film 1130 is heated above its transition temperature, the coupled stamper 1190/embossable film 1130 may be cooled to a lower temperature down to approximately the glass transition temperature of the embossable film 1130 prior to separation. Alternatively, for another example, the coupled stamper 1190/embossable film 1130 may be cooled to a temperature in the range of approximately at the transition temperature of the embossable film 1130 to just above room temperature. In yet another embodiment, the coupled stamper 1190/embossable film 1130 may be cooled to room temperature and then separated.

FIG. 6C illustrates an alternative embodiment of imprinting an embossable film including preheating the embossable film prior to imprinting. In this embodiment, embossable film 1130 and stamper 1190 may be separately heated. In step 1212, after disposing embossable film 1130 over the base structure, this structure may be preheated to the embossing temperature prior its introduction into die assembly 230 by, for example, pick-up head 212 of FIG. 2. In step 1214, the preheated embossable film 1130/base structure 1115 is positioned in close proximity (e.g., nest area of lower die assembly 214) to the stamper 1190. Alternatively, the embossable film 1130/base structure 1115 may be preheated to a temperature below that of (e.g., close to) the embossing temperature and then heated to the embossing temperature during or after its positioning in the nest area of lower die assembly 214. Alternatively, the embossable film 1130/base structure 1115 may be preheated to the stamper's temperature/embossing temperature and imprinted after its close positioning to stamper 1190. Stamper 1190 is then pressed into the embossable film 1130 at the embossing temperature, step 1230. The stamper 1190 is then separated from embossable film 1130 after imprinting, step 1240. In one embodiment, the embossable film 1130/base structure 1115 may be removed from close proximity to stamper 1190, step 1241, and then cooled to a temperature below the glass transition temperature of embossable film 1130. The stamper 1190 is then separated from embossable film 1130 after imprinting. In one embodiment, the embossable film 1130/base structure 1115 may be removed from close proximity to stamper 1190 and then cooled to a temperature below the glass transition temperature of embossable film 1130, step 1243.

An imprinted pattern of trenches areas (a.k.a., recessed areas, grooves, valleys, etc.) and plateaus (a.k.a., raised areas) is thereby formed in the embossable film 1230 (as illustrated in FIG. 5B). Following the imprinting of a pattern into embossable film 1130, a subtractive or an additive process may be used to form the desired DTR pattern in the disk. In a subtractive process, for example, one or more layers disposed above the base structure 1115 may be removed (e.g., through imprint lithography and etching) to expose a desired pattern on layer 1120 (e.g., a NiP or soft magnetic layer). Alternatively, the DTR pattern may be formed in base structure 1115. In an additive process where layer 1120 is, for example, a NiP layer, a material compatible or identical to material forming the initial NiP layer is added or plated to form the raised areas 1110 of the discrete track recording pattern.

In one embodiment, the imprinting of an embossable film 1130 may be performed at approximately room temperature using an embossable material that does not have a glass transition temperature (Tg), for examples, thermosetting (e.g., epoxies, phenolics, polysiloxanes, ormosils, silica-gel) and radiation curable (e.g., UV curable, electron-beam curable) polymers. Silica-gel may be obtained from industry manufacturers, for example, SOL-GEL available from General Electric Corp., of Waterford N.Y. In another embodiment, a thermo plastic material, for example, a polymer such as Ultem available from General Electric Corp., of Waterford N.Y. may be used for the embossable film. In such an embodiment, for example, the use of a disk heater (e.g., pick-up head 212) may not be necessary since an elevated temperature of a substrate need not be maintained during transport to stamper 1190.

As previously noted, the apparatus and methods discussed herein may be used with various types of base structures (e.g., optical disk substrates and wafer substrates, panel substrates) having embossable films. For example, the imprinting system discussed herein may be used in the production of optical recording disks, semiconductor wafers, liquid crystal display panels, etc. In one embodiment, the apparatus and methods discussed herein may be used with various types of base structures (e.g., wafer and panel oxide/substrates) having an embossable layer disposed thereon. In an alternative embodiment, for example, the imprinting apparatus and methods discussed herein may be used to fabricate semiconductor devices such as, for example, a transistor. In such a fabrication, an embossable layer may be disposed above a base structure of, for example, an oxide (e.g., SiO₂) layer on top of a silicon wafer substrate. A stamper may be generated with a patterned structure for active areas of the transistor. The stamper is imprinted into the embossable layer with the embossed pattern transferred into the oxide layer using etching techniques (e.g., reactive ion etching). Subsequent semiconductor wafer fabrication techniques well known in the art are used to produce the transistor.

In an alternative embodiment, for example, the imprinting apparatus and methods discussed herein may be used to fabricate pixel arrays for flat panel displays. In such a fabrication, an embossable layer may be disposed above a base structure of, for example, an indium tin oxide (ITO) layer on top of a substrate. The stamper is generated with a patterned layer being an inverse of the pixel array pattern. The stamper is imprinted into the embossable layer with the embossed pattern transferred into the ITO using etching techniques to pattern the ITO layer. As a result, each pixel of the array is separated by an absence of ITO material (removed by the etching) on the otherwise continuous ITO anode. Subsequent fabrication techniques well known in the art are used to produce the pixel array.

In yet another embodiment, as another example, the imprinting apparatus and methods discussed herein may be used to fabricate lasers. In such a fabrication, embossable material areas patterned by the stamper are used as a mask to define laser cavities for light emitting materials. Subsequent fabrication techniques well known in the art are used to produce the laser. In yet other embodiments, the apparatus and methods discussed herein may be used in other applications, for example, the production of multiple layer electronic packaging, the production of optical communication devices, and contact/transfer printing.

In the foregoing specification, the invention has been described with reference to specific exemplary embodiments thereof. It will, however, be evident that various modifications and changes may be made thereto without departing from the broader spirit and scope of the invention as set forth in the appended claims. For example, although figures and methods herein are discussed with respect to single-sided imprinting, they may be used for double-sided imprinting as well. The specification and figures are, accordingly, to be regarded in an illustrative rather than a restrictive sense.

1. A method, comprising:
positioning a substrate having an outer dimension near an embossing foil; and
checking the substrate for drift relative to the embossing foil.

2. The method of claim 1, wherein positioning further comprises centering the substrate relative to the embossing foil.

3. The method of claim 2, wherein positioning further comprises engaging the outer dimension with a plurality of rods coupled to actuators.

4. The method of claim 3, wherein checking further comprises repositioning the substrate.

5. The method of claim 4, wherein repositioning further comprises controlling the actuators with an actuator control algorithm.

6. The method of claim 1, wherein positioning further comprises maintaining an embossable film disposed above the substrate at a pre-heated temperature.

7. The method of claim 1, further comprising pressing the embossing foil into the embossable film.

8. The method of claim 1, further comprising separating the embossable film from the embossing foil.

9. The method of claim 8, further comprising cooling the embossable film.

10. An apparatus, comprising:
means for positioning a substrate near an embossing foil; and
means for checking a drift of the substrate relative to the embossing foil.

11. The apparatus of claim 10, wherein means for positioning further comprises means for centering the substrate relative to the embossing foil.

12. The apparatus of claim 10, wherein means for checking further comprises means for repositioning the substrate relative to the embossing foil.

13. The apparatus of claim 10, wherein means for positioning further comprises means for maintaining a pre-heated temperature of an embossable film disposed above the substrate.

14. An apparatus, comprising:
an embossing foil;
a nest disposed below the embossing foil, the nest having an gas-bearing surface to receive a substrate having an outer dimension; and
a plurality of piezo actuators disposed near the gas-bearing nest, the plurality of piezo actuators to engage the outer dimension to center the substrate relative to the embossing foil.

15. The apparatus of claim 14, further comprising a controller coupled to the plurality of piezo actuators to sense a motion stoppage of the substrate.

16. The apparatus of claim 14, wherein the plurality of piezo actuators comprise a push rod to engage the outer dimension of the substrate.

17. The apparatus of claim 14, wherein the plurality of piezo actuators comprise nano actuators.

18. The apparatus of claim 14, further comprising an actuator control algorithm to control the plurality of piezo actuators while engaged with the outer dimension.

19. The apparatus of claim 14, wherein the nest is defined by a wall, and wherein the gas-bearing surface prevents the substrate from making mechanical contact with the nest.

20. The apparatus of claim 14, wherein the substrate comprises a disk having an outer diameter to engage the plurality of piezo actuators.
